(19) United States
(12) Patent Application Publication
(10) Pub. No.: US 2014/0290985 A1
(43) Pub. Date: Oct. 2, 2014

(54) EMBEDDED METAL STRUCTURES IN CERAMIC SUBSTRATES

(71) Applicant: Ceram Tec GmbH, Plochingen (DE)

(72) Inventors: Alexander Dohn, Memmelsdorf (DE); Klaus Herrmann, Thiersheim (DE); Alfred Thimm, Wunsiedel (DE); Oskar Helgert, Wiesau (DE); Roland Leneis, Marktredwitz (DE); Sigurd Adler, Affalterbach (DE)

(21) Appl. No.: 14/358,252

(22) PCT Filed: Nov. 16, 2012
(86) PCT No.: PCT/EP2012/072824

§ 371 Date: May 15, 2014

(30) Foreign Application Priority Data
Nov. 16, 2011 (DE) 102011086464.4

(51) Int. Cl. H05K 1/02; H05K 1/03; H05K 3/10

(52) U.S. Cl. CPC H05K 1/0296; H05K 3/107; H05K 1/0306
USPC 174/251; 29/852

(57) ABSTRACT

The invention relates to a method for producing a substrate comprising embedded conductive metal structures or metallizations, in particular for use as printed circuit boards. The aim of the invention is to allow the buried metallization of three-dimensional, i.e. curved or angular, substrates in addition to the two-dimensional flat and level, i.e. plate-shaped, substrates. According to the invention, this is achieved in that trenches and/or recesses are dug into the substrate using laser technology, and the metal structures are then produced in the trenches and/or recesses.

The invention relates to a method for producing a substrate having embedded conducive metal structures and/or metallizations, in particular for use as circuit boards and a substrate produced using this method.

Embedded conductive structures are known from multichip module technology, in which metallic structures (printed conductors, electric contact points) printed by the thick film technique are laminated in circuit boards that have not yet been cured, such as ceramic films, under pressure and temperature. However, this is possible only so the case of flat, i.e., two-dimensional, boards. Furthermore, the printed conductors must not be too high (or thick) (max 10-20 μm); otherwise they can no longer be impressed deeply.

The object of the invention is to improve upon a method according to the definition of the species of claim 1, so that in addition to the two-dimensional, flat and planar, i.e., board-like, substrates, three-dimensional, i.e., curved or angular, substrates may also be metallized, preferably deeply and on multiple sides.

According to the invention, this object is achieved due to the fact that trenches and/or recesses are cut into the substrate using laser technology and then the metallic structures are created in the trenches and/or recesses.

Two-dimensional flat and planar and in particular also three-dimensional, i.e., curved or angular, bodies may be metallized deeply on multiple sides in this way. These bodies include, for example, ceramic substrates to which metallized regions are applied, so they can be used as circuit boards. This is the case in particular when chips or whole secondary circuits of polyimide, for example, are to be positioned.

The substrate therefore has a geometry that deviates from that of a planar board, i.e., having a three-dimensional curvature or angles. This is possible due to the use of a laser. Three-dimensional complex geometries are possible in this way.

In a preferred embodiment, the substrate is a ceramic substrate or a plastic substrate.

A ceramic substrate consists preferably of an AlN ceramic, in which Al is produced by decomposition after cutting with a laser in the trenches and/or recesses, and this Al is then further reinforced by using known methods such as currentless [deposition of] nickel, gold or copper and alloys thereof or a mixture thereof.

Alternatively, after embedding, the ceramic substrate is immersed in an organic metal salt solution, e.g., silver acetate or copper acetate, and then is exposed using a suitable laser, wherein the metal salts are converted to elements which bind firmly to the ceramic.

An oxide or glass-forming additives such as zinc acetate or silicones are preferably added to the metal salts.

In one embodiment, after embedding, the trenches and/or recesses are filled with a thick film paste of a metal and then sintered with a suitable laser directly in the laser track, i.e., in the trenches and/or recesses.

In one embodiment of the invention, the exposed locations outside of the trenches and/or recesses or in partial regions of the trenches and/or recesses are washed off or ground off.

In one embodiment of the invention, the metallizations are reinforced in a currentless or cathodic process in the trenches and/or recesses and/or are coated with covering metals.

The metallizations created in the trenches and/or recesses preferably form a closure with the surface of the substrates at one level and do not protrude out of the substrate and are therefore stackable.

A substrate according to the invention, having embedded conductive metallic structures and/or metallizations produced using the method described above is characterized in that the metallic structures and/or metallizations have a vertical thickness, measured with respect to the surface of the substrate, of mere than 30 μm, especially preferably more than 40 μm, most especially more than 45 μm and even 50 μm in an important application case.

With the invention described hereinafter, two-dimensional, flat and planar, but especially also three-dimensional, i.e., curved or angular, bodies may also be metallized deeply on multiple sides. These bodies are ceramic substrates, for example, to which metallized regions are applied and which are used as circuit boards.

This is advisable when, among other things, chips or entire secondary circuits of polyimide are to be positioned.

The invention describes a ceramic substrate (preferably three-dimensional) or a plastic substrate with embedded conductive metallic structures and/or metallization produced from a ceramic or organic chemical base body into which trenches and/or recesses for the metallic structures are cut using laser technology. Then the metallization is created in the trenches and/or recesses. A three-dimensional ceramic substrate is understood to be a geometry which deviates from a planar board.

For metallization, Al, for example, can be produced from an AlN ceramic in the trenches and/or recesses by decomposition using a laser in the case of a ceramic substrate made of an AlN ceramic. This Al is then further reinforced by known methods, such as currentless [deposition of] nickel, gold or copper and their alloys or a mixture thereof.

Alternatively, the ceramic substrate and/or the ceramic body with the trenches and/or recesses may be immersed in an organic metal salt solution, for example, silver acetate or copper acetate, then the metal salts in the trenches and/or recesses are exposed using a suitable laser, and the metal salts are converted to the elements, which then bind securely to the ceramic. To improve adhesion, an oxide or glass-forming additives such as zinc acetate or silicone may be added to the metal salts. Alternatively, it is also possible to perform metallization using a conventional thick film paste, which is used to fill the trenches and/or recesses or the layout. Then sintering is performed using a suitable laser directly in the laser track, i.e., in the trenches and/or recesses. Any excess unsintered areas can then be removed with an aqueous detergent with ultrasonic support.

The unexposed areas outside of the trenches and/or recesses or in partial regions of the trenches and/or recesses must simply be washed off or ground off. The metallization in the trenches and/or recesses may then be reinforced further in a currentless or cathodic process and/or coated with covering metals.

This yields metallizations that are sealed with the ceramic on a plane and are therefore very suitable for combination with circuit chips or flexible circuits (e.g., in/on polyimide).

Such laser-eroded ceramics, which have been rendered conductive in trenches and/or recesses, could also be used to produce prototypes of metallized circuits in/on ceramics particularly quickly. A layout drawing could thus be scanned on a copy machine and converted directly to laser commands to control the laser.

The present invention closes a gap between thin film and thick film metallization. Heavy metallizations or even metallizations of different thicknesses on a component with coarse and fine structures are possible concurrently.

### EXAMPLE 1

Trenches and/or recesses with a depth of 50 μm are lasered into a sintered ceramic substrate (ceramic substrate) made of AlN of the size 114×114×2 mm in lasering a thin layer of aluminum is formed from the decomposition of AlN→Al+0.5 N₂ by laser light. This layer of aluminum is reinforced by placing the sintered ceramic substrate in a chemical nickel bath for 30 minutes (Ni²⁺, usually dissolved in the bath as a sulfamate, is reduced by reducing agents such as sodium hypophosphite on a “seeded” surface of Pd and later reduced to elemental Ni after covering these Pd seeds with the nickel itself that has already been deposited; the seeding on tungsten, for example, is produced by immersion in a solution of Pd²⁺, usually a highly dilute palladium(II) chloride solution or ammonium tetrachloropalladate(II) solution). Then a thin layer of O, 1 μm gold is applied in a currentless process. The result is a ceramic with embedded, electrically conductive structures, such as those used as carriers for electric/electronic elements, for example. The conductive structures are preferably completely situated in the ceramic, i.e., they do not protrude out of the surface of the ceramic.

### EXAMPLE 2

A structure (trenches and/or recesses) with a depth of 50 μm is created using an excimer laser in a sintered ceramic substrate (ceramic substrate) made of AlN in the size 114×114×2 mm with a defined layout. The ceramic is immersed in a solution of 10% silver acetate and 5% polyvinyl alcohol (for thickening). Then the part is dried at 70° C. Using a Fineline laser, the metal salt layer is converted to silver metal in the recesses formed previously by decomposing the acetate by the heat applied. In deionized water (demineralized water) at 80° C. the undecomposed regions are dissolved again with silver acetate-polyvinyl alcohol. The silver layer can be reinforced cathodically with gold until achieving a planar seal of the trenches and the ceramic.

A method for producing the substrates according to the invention is characterized by the following method steps, which are to be performed in order.
1) Trenches and/or recesses are created in a ceramic or organic chemical base body (ceramic substrate or plastic substrate) using a laser technique.
2) Then the metallization is introduced into or created in the recesses.
3) The metallization in the trenches and/or recesses preferably forms a planar seal with the surface of the substrate, i.e., the metallization is embedded in the substrate.

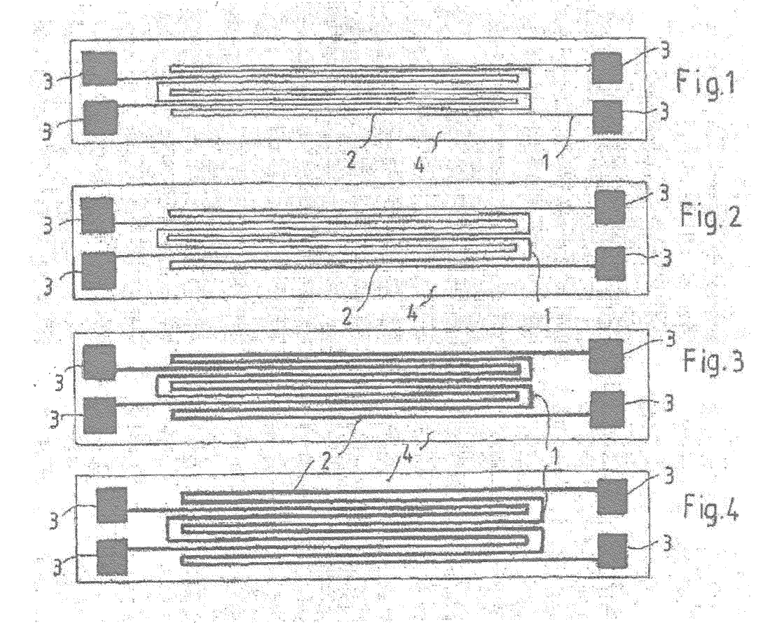

FIGS. 1 to 4 show various metallizations 1 on a ceramic substrate 4. Metallizations in the form of printed conductors are labeled with reference numeral 2 and electric contact points are labeled with reference numeral 3. FIG. 5 shows a three-dimensional ceramic substrate with a metallization 1, which is embedded in the ceramic substrate 4 and does not protrude out of the surface.

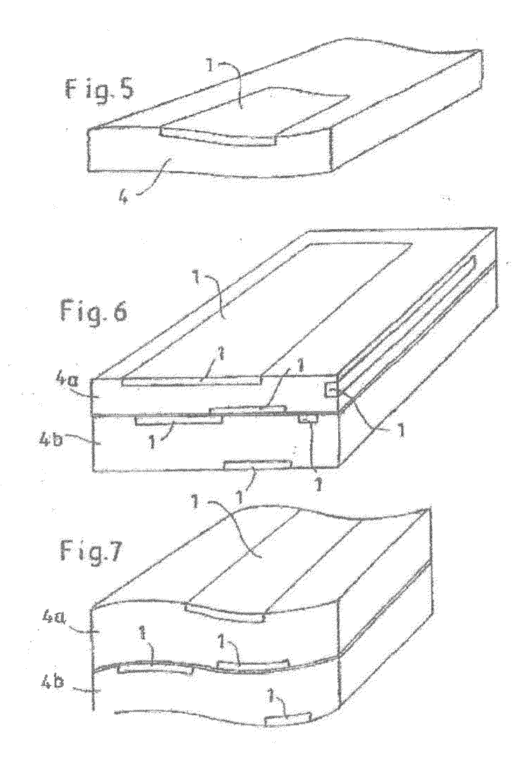

Due to the fact that the metallization is embedded, a plurality of substrates, each having embedded metallic structures, can be stacked one above the other without the metallization being damaged by the substrate above it. This is illustrated in FIG. 6. Two ceramic substrates 4a, 4b are designed here as circuit boards and are combined to form one unit. Metallizations 1 are embedded in the ceramic substrate and do not protrude out of the surface. The individual metallizations 1 form printed conductors and electric contact points. FIG. 6 shows two three-dimensional ceramic substrates 4a, 4b with embedded metallizations 1.

The metallization may of course also be introduced on both sides of a substrate.

1-13. (canceled)

14. A method for producing a substrate with embedded conductive metallic structures or metallizations wherein trenches or recesses are cut in the substrate using a laser technique and then the metallic structures are created in the trenches and recesses.

15. The method according to claim 14, wherein the substrate has a non-planar geometry.

16. The method according to claim 14, wherein the substrate is a ceramic substrate or a plastic substrate.

17. The method according to claim 14, wherein a ceramic substrate comprises an AlN ceramic and is created by decomposing Al using a laser after embedding it in the trenches and/or recesses, and then reinforcing this Al further by known methods, such as currentless deposition of nickel, gold or copper and their alloys or a mixture thereof.

18. The method according to claim 17, wherein the ceramic substrate is immersed in an organic metal salt solution after being embedded, and then the metal salts in the trenches and/or recesses are exposed with a suitable laser, wherein the metal salts are converted to elements which adhere firmly to the ceramic.

19. The method according to claim 17, wherein an oxide or glass-forming additives such as zinc acetate or silicone are added to the metal salts.

20. The method according to claim 16, wherein after cutting the trenches and/or recesses, they are filled with a thick film paste of a metal and then are sintered directly in the laser trace using a suitable laser, i.e., in the trenches and/or recesses.

21. The method according to claim 14, wherein the unexposed areas outside of the trenches and/or recesses or in partial regions of the trenches and/or recesses are washed off or ground off.

22. The method according to claim 14, wherein the metallization in the trenches and/or recesses is reinforced cathodically or in a currentless process and/or is coated with covering metals.

23. The method according to claim 14, wherein the metallization created in the trenches and/or recesses forms a seal with the surface of the substrate on one level and does not protrude out of the substrate and therefore the substrates can be stacked.

24. A substrate with embedded conductive metallic structures and/or metallization produced by a method according to claim 14, wherein the metallic structures and/or metallizations have a vertical thickness of greater 20 than 30 μm, measured with respect to the surface of the substrate.

25. The substrate according to claim 24 with a vertical thickness of greater than 40 μm.

26. The substrate according to claim 24 with a vertical thickness greater than 45 μm.
